(19) United States
(12) Patent Application Publication
(10) Pub. No.: US 2026/0171752 A1
(43) Pub. Date: Jun. 18, 2026

(54) DIRECTLY MODULATED LIGHT SOURCE

(71) Applicant: COMMISSARIAT À L'ENERGIE ATOMIQUE ET AUX ENERGIES ALTERNATIVES, PARIS (FR)

(72) Inventors: Joan RAMIREZ, PALAISEAU (FR); Claire BESANCON, PALAISEAU (FR)

(21) Appl. No.: 19/412,707

(22) Filed: Dec. 8, 2025

(30) Foreign Application Priority Data
Dec. 12, 2024 (FR) 2413946

(51) Int. Cl. H01S 5/06; H01S 5/343

(52) U.S. Cl. CPC H01S 5/0614; H01S 5/343

(57) ABSTRACT

A directly modulated light source includes: a horizontal laser diode including a horizontal PIN junction, the horizontal junction being formed of an intrinsic zone arranged between a first p-doped zone and a first n-doped zone, the intrinsic zone including quantum wells; a vertical PIN junction formed of the intrinsic zone arranged between a second p-doped zone and a second n-doped zone, the latter zone being arranged on the substrate side; the vertical junction being reverse biased and modulates the light emitted by the horizontal laser diode by the Stark effect in the quantum wells; a blocking layer arranged beneath the first p-doped zone and to prevent current leakage between the first p-type doped zone and the second n-doped zone.

### CROSS-REFERENCE TO RELATED APPLICATION

This application claims priority to foreign French patent application No. FR 2413946, filed on Dec. 12, 2024, the disclosure of which is incorporated by reference in its entirety.

### FIELD OF THE INVENTION

The invention relates to a directly modulated light source, and in particular to a directly modulated light source using the Stark effect.

### BACKGROUND

Directly modulated lasers of the prior art contain laser diodes the injection current of which is modulated via an analogue electronic signal. In order to generate optical zeros, the injection must therefore be discontinuous, that is to say alternate between 0 and a predetermined electric current value.

This discontinuity in the injection of electric current brings about changes in the density of carriers in the conduction band as well as changes in the operating temperature of the diode, due to heating by Joule effect caused by the injection of the current. These phenomena, which cause the index of the active material of the laser diode to change, cause “chirps” (that is to say a signal in which the frequency increases or decreases over time) and limit the bandwidth to a few tens of GHz. It is possible to improve the transmission distance of the fibre by using external ring resonators. However, such devices take into account two control signals (one for the laser and one for the modulator), have a higher sensitivity to temperature and are subject to non-linearities in the ring starting from medium-high coupled optical power, this leading to distortion of the signal.

In order to limit these drawbacks, it is possible to use an external modulation laser. In an external modulation laser, unlike in the directly modulated laser, the current is injected into the laser diode continuously, and modulators (typically diodes too) are used to modulate the optical signal coming from the laser by means of a reverse voltage. This voltage induces a current in the modulators (typically that of a reverse III-V PIN diode) that is lower than that which is injected into the diode. There is therefore no major change in temperature, and therefore no major change in the refractive index of the active material of the diode, thus reducing the chirp. External modulation lasers thus allow optical links over distances of greater than 10 km.

However, electro-absorption modulators used for the external modulation require two drivers and they produce a modulated power lower than that of direct modulation lasers, due to insertion loss in the electro-absorption modulator. External modulation lasers can also be difficult to set up since it is necessary to avoid saturating the input of the modulator in order to avoid degrading the optical modulation amplitude. Ideally, the electro-absorption modulator should operate in linear mode and should have a forbidden band of different material in order to minimize insertion losses. Such requirements involve complex and expensive manufacturing technology with precise forbidden band calibration compared to directly modulated lasers.

### SUMMARY OF THE INVENTION

In order to overcome the aforementioned drawbacks of laser diodes, the invention proposes a directly modulated light source comprising:
a so-called horizontal laser diode comprising a substrate and a first, so-called horizontal, PIN junction extending along an X axis of an XYZ coordinate system defining an XY horizontal plane parallel to said substrate and a vertical Z axis, the first PIN junction being formed of an intrinsic zone arranged between a first p-type doped zone and a first n-type doped zone, the intrinsic zone comprising a stack of quantum wells arranged perpendicular to the Z axis;
the horizontal laser diode being intended to be forward biased and configured to emit light along the Y axis when a direct electric current is injected into the horizontal junction;
a second, so-called vertical, PIN junction extending along the Z axis and formed of said intrinsic zone arranged between a second p-type doped zone and a second n-type doped zone, the latter zone being arranged on the substrate side;
the vertical junction being intended to be reverse biased and configured to modulate said light emitted by the horizontal laser diode when an alternating electric field along the Z axis is applied to said intrinsic zone, said modulation being achieved through the Stark effect in the quantum wells; and
a blocking layer arranged at least beneath the first p-type doped zone and configured to prevent current leakage between the first p-type doped zone and the second n-type doped zone.

In one embodiment, the blocking layer is made of insulating or semi-insulating material.

In one embodiment, the material is semi-insulating InP.

In one embodiment, the blocking layer comprises a third p-type zone and a third n-type zone forming a diode configured to be reverse biased.

In one embodiment, the intrinsic zone of the horizontal laser diode is optically coupled to a distributed feedback grating.

In one embodiment, the substrate is made of InP or GaAs material.

In one embodiment, the directly modulated light source further comprises a semi-insulating layer made of crystalline material arranged on the substrate and in contact with the blocking layer and the second n-type doped zone.

In one embodiment, the substrate and the semi-insulating layer are made of InP material.

The following description presents a number of exemplary embodiments of the device of the invention: these examples do not limit the scope of the invention. These exemplary embodiments contain not only the features essential to the invention, but also additional features associated with the embodiments in question.

### BRIEF DESCRIPTION OF THE DRAWINGS

A better understanding of the invention will be obtained and other advantages will become apparent on reading the description which will follow, given without limitation, and by virtue of the figures, among which:

FIG. 1a illustrates a directly modulated light source according to the invention, seen in cross section;

FIG. 1b illustrates a directly modulated light source according to the invention, seen from above;

FIG. 2a illustrates an example of a directly modulated light source, seen in cross section;

FIG. 2b illustrates another example of a directly modulated light source, seen in cross section; and

FIG. 3 illustrates an equivalent circuit diagram of a directly modulated light source according to the invention.

### DETAILED DESCRIPTION

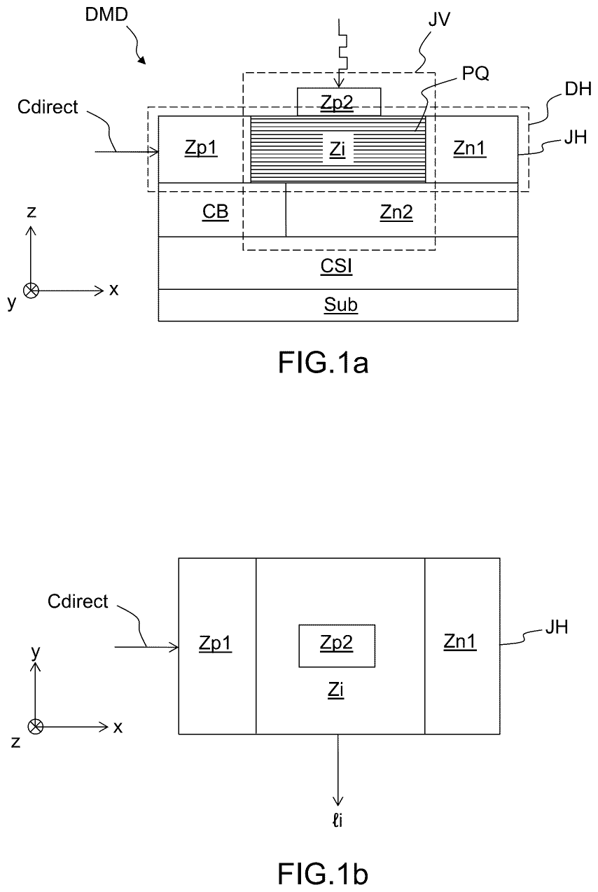

The invention relates to a directly modulated light source. FIG. 1a and FIG. 1b illustrate a directly modulated light source DMD according to the invention, seen in cross section and seen from above, respectively.

The directly modulated light source DMD comprises a so-called horizontal laser diode DH comprising a substrate Sub and a first, so-called horizontal, PIN junction JH extending along an X axis of an XYZ coordinate system defining an XY horizontal plane parallel to the substrate and a vertical Z axis. The first PIN junction is formed of an intrinsic zone Zi arranged between a first p-type doped zone Zp1 and a first n-type doped zone Zn1, the intrinsic zone Zi comprising a stack of quantum wells PQ arranged perpendicular to the Z axis. The zone Zi constitutes the active zone of the laser diode DH.

The horizontal laser diode DH is intended to be forward biased and is configured to emit light li along the Y axis when a direct electric current Cdirect is injected into the horizontal junction JH. By way of example, a direct current generator DCV injects a direct electric current Cdirect into the horizontal junction JH. The current is injected laterally in relation to the quantum wells PQ. Typically, the direct current Cdirect is generated using a direct current generator DCV.

The directly modulated light source DMD also comprises a second, so-called vertical, PIN junction JV extending along the Z axis and formed of the intrinsic zone Zi arranged between a second p-type doped zone Zp2 and a second n-type doped zone Zn2. The second n-type doped zone Zn2 is arranged between the intrinsic zone Zi and the substrate. The horizontal junction JH and the vertical junction JV thus have the same intrinsic zone Zi.

The vertical junction JV is intended to be reverse biased and is configured to modulate the light li emitted by the horizontal laser diode DH when an alternating electric field along the Z axis is applied to the intrinsic zone Zi. The modulation is achieved through the quantum-confined Stark effect in the quantum wells PQ of the active zone.

By way of example, a square-wave voltage generator ACV injects a square-wave voltage into the vertical junction JV, thus producing an electric field perpendicular to the quantum wells. Since the vertical junction is reverse biased, very little current is injected via the junction JV, and the injection of carriers into the junction JH is not disturbed.

In addition, the directly modulated light source DMD comprises a blocking layer CB arranged at least beneath the first p-type doped zone Zp1 and configured to prevent current leakage between the first p-type doped zone Zp1 and the second n-type doped zone Zn2. The width along the X axis of the blocking layer CB is greater than that of the p-type doped zone Zp1. In other words, the blocking layer CB is arranged so as to prevent the first p-type doped zone Zp1 and the second n-type doped zone Zn2 from being in contact.

The quantum wells are configured to be modulated by the quantum-confined Stark effect. In particular, in the invention, the quantum-confined Stark effect is produced when an electric field is applied perpendicular to the quantum wells.

In general, the Stark effect occurs when an atom or a molecule is placed in an external electric field. The electric field interacts with the charged particles inside the atom or molecule, causing a division of energy levels. The strength of the electric field determines the extent of the division. In the absence of confinement, this effect is difficult to exploit since the wave functions of the electron and of the hole move away very quickly. In the quantum-confined Stark effect, the wave functions are confined in the quantum wells, the superposition of the states modified by the electric field is improved and an instantaneous reduction in the forbidden band of the quantum wells is observed (Miller et al., Band-Edge Electroabsorption in Quantum Well Structures: The Quantum-Confined Stark Effect, Phys. Rev. Lett. 53, 22, 1984).

In the present invention, when a square-wave alternating voltage (as shown in FIG. 1a) oscillating between two predetermined values is applied to the quantum wells, an electric field perpendicular to the quantum wells is generated. Under the action of the electric field, the electronic state of the quantum wells is modified. The forbidden band of the quantum wells is thus reduced rapidly, owing to the quantum-confined Stark effect. This makes it possible to modulate the light li emitted by the horizontal diode DH, by absorbing the light li which is transmitted through the quantum wells or by letting it pass through. The light li is therefore modulated directly using the quantum-confined Stark effect, inside the light source DMD. The modulation of the electric field, through the vertical junction, in the intrinsic zone Zi therefore makes it possible to modulate the light li emitted by the horizontal diode DH. Typically, the alternating voltage is produced by a square-wave voltage generator ACV.

The invention thus makes it possible to obtain a directly modulated light source DMD using the quantum-confined Stark effect, which can be integrated into a laser source. Advantageously, the use of the quantum-confined Stark effect directly in the light source makes it possible to use a constant direct current injection into the horizontal laser diode DH while having effective intensity modulation owing to the vertical electric field, all in a single component. The direct current avoids the refractive index changes normally brought about by a discontinuously injected current (as is the case for directly modulated lasers of the prior art). The direct current thus makes it possible to reduce the chirp normally generated in directly modulated lasers of the prior art.

In addition, the use of the quantum-confined Stark effect directly in the light source allows for simplified manufacture and design, without external modulators, in contrast to external modulation lasers. Thus, the present invention makes it possible to obtain a simple laser source, at low cost, and with reduced chirp.

The directly modulated laser according to the invention therefore does not have the drawbacks of the directly modulated lasers according to the prior art, while retaining the advantages, such as simplicity of manufacture and design, low cost and high power.

In one embodiment, the substrate Sub is made of InP or GaAs material. Advantageously, the various layers of the DMD light source are produced by epitaxy from the substrate. Thus, a substrate made of InP or GaAs allows the epitaxial growth of the quantum wells PQ directly on the substrate Sub.

The choice of the substrate and associated layers depends on the desired emission wavelength. A substrate made of InP allows the light source DMD to be implemented at a telecommunication wavelength, that is to say at wavelengths of greater than 1 μm.

In another embodiment, the substrate Sub is arranged on a second substrate, made of silicon, thus allowing the light source DMD to be used in a chip, for example.

The horizontal laser diode DH comprises an optical cavity which makes it possible to emit the light li along the Y axis when a direct electric current Cdirect is injected into the horizontal junction JH. In one embodiment, the optical cavity may be defined by means of two distributed Bragg reflector (DBR) mirrors per facet (that is to say by cleaving the component to expose a facet which is treated by anti-reflection treatment of which the thicknesses of the deposited materials are adjusted so as to obtain a defined reflection coefficient) or by using a resonator extending along the Y axis. The optical cavity may also be defined by a distributed feedback (DFB) grating in a III-V material or in an optical guide made up of another material (silicon, silicon nitride, lithium niobate or other), extending along the Y axis. The intrinsic zone Zi of the horizontal laser diode DH is thus optically coupled to the distributed feedback grating DFB.

Advantageously, the distributed feedback Bragg grating DFB makes it possible to obtain single-mode laser emission useful for optical communications.

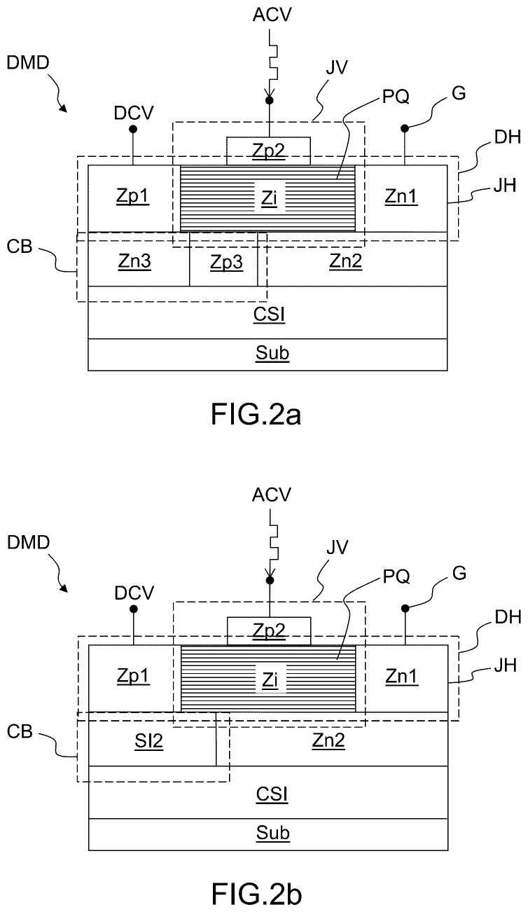

In one embodiment, illustrated in FIG. 2a, the blocking layer CB comprises a third p-type zone Zp3 and a third n-type zone Zn3 forming a diode DI configured to be reverse biased. Advantageously, the third p-type zone Zp3 is in contact with the second n-type zone Zn2, so that the second n-type zone Zn2 is not in contact with the first n-type zone Zn1, thus preventing current from flowing from the first p-type doped zone Zp1 to the second n-type doped zone Zn2. Advantageously, the reverse-biased diode makes it possible to have a blocking layer of thin thickness.

In another embodiment, illustrated in FIG. 2b, the blocking layer CB is made of insulating or semi-insulating material SI2. For example, the material is semi-insulating InP. Advantageously, the layer made of semi-insulating InP has a width greater than the width of the p-type doped zone Zp1.

In one embodiment, the crystalline structure of the blocking layer CB allows the epitaxial growth of layers arranged above the blocking layer, and in particular the first p-type doped zone Zp1.

In one embodiment, the directly modulated light source DMD further comprises a semi-insulating layer CSI made of crystalline material arranged on the substrate and in contact with the blocking layer CB and the second n-type doped zone Zn2. The semi-insulating layer CSI prevents current from flowing from the vertical junction JV to the substrate Sub. The crystalline structure of the semi-insulating layer CSI allows the epitaxial growth of layers arranged above the semi-insulating layer CSI, and in particular the blocking layer and the second p-type doped zone Zp2. In one example, the semi-insulating layer CSI is made of InP, thus allowing for use at telecommunication wavelengths.

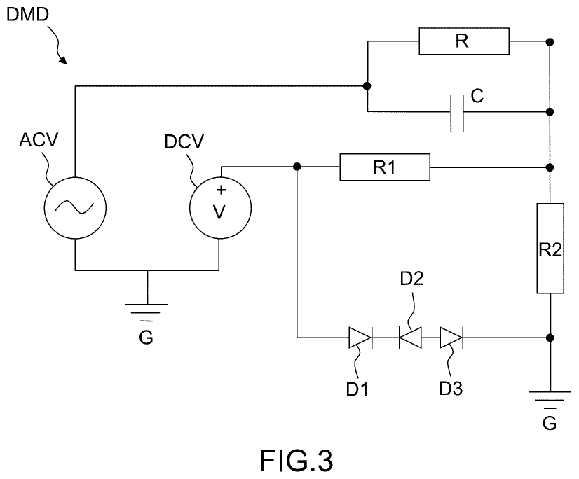

For example, the substrate and the semi-insulating layer CSI are made of crystalline InP, thus allowing for emission at telecommunication wavelengths. FIG. 3 illustrates an example of an equivalent circuit diagram of a directly modulated light source DMD according to the embodiment of FIG. 2a. The equivalent circuit diagram comprises a first, forward-biased, diode D1 which corresponds to the junction between the first p-doped zone Zp1 and the third n-doped zone Zn3, a reverse-biased diode D2 which corresponds to the junction between the third n-doped zone Zn3 and the third p-doped zone Zp3, and a third, forward-biased, diode D3 which corresponds to the junction between the third p-doped zone Zp3 and the second n-doped zone Zn2. The equivalent circuit diagram also comprises two generators DCV, ACV. The direct current generator DCV makes it possible to inject the direct electric current Cdirect into the horizontal junction. The square-wave voltage generator ACV makes it possible to inject the voltage oscillating between two predetermined values into the vertical junction JV. The resistor R represents the resistance of the vertical junction JV and the capacitor C represents the capacitance induced by the vertical junction. The resistors R1 and R2 represent the intrinsic resistance of the quantum wells, the resistor R1 representing the left-hand part of the quantum wells (before the contact with the second p-doped zone Zp2) and the resistor R2 representing the right-hand part of the quantum wells.

Although the invention has been illustrated and described in detail using one preferred embodiment, the invention is not limited to the disclosed examples. Other variants may be inferred by those skilled in the art without departing from the scope of protection of the claimed invention.

1. A directly modulated light source (DMD) comprising:
a so-called horizontal laser diode (DH) comprising a substrate (Sub) and a first, so-called horizontal, PIN junction (JH) extending along an X axis of an XYZ coordinate system defining an XY horizontal plane parallel to said substrate and a vertical Z axis, the first PIN junction being formed of an intrinsic zone (Zi) arranged between a first p-type doped zone (Zp1) and a first n-type doped zone (Zn1), the intrinsic zone (Zi) comprising a stack of quantum wells (PQ) arranged perpendicular to the Z axis;
the horizontal laser diode being intended to be forward biased and configured to emit light (li) along the Y axis when a direct electric current (Cdirect) is injected into the horizontal junction;
a second, so-called vertical, PIN junction (JV) extending along the Z axis and formed of said intrinsic zone (Zi) arranged between a second p-type doped zone (Zp2) and a second n-type doped zone (Zn2), the latter zone being arranged on the substrate side;
the vertical junction (JV) being intended to be reverse biased and configured to modulate said light emitted by the horizontal laser diode when an alternating electric field along the Z axis is applied to said intrinsic zone (Zi), said modulation being achieved through the Stark effect in the quantum wells; and
a blocking layer (CB) arranged at least beneath the first p-type doped zone (Zp1) and configured to prevent current leakage between the first p-type doped zone (Zp1) and the second n-type doped zone (Zn2).

2. The directly modulated light source (DMD) according to claim 1, wherein the blocking layer is made of insulating or semi-insulating material.

3. The directly modulated light source (DMD) according to claim 2, wherein the material is semi-insulating InP.

4. The directly modulated light source (DMD) according to claim 1, wherein the blocking layer comprises a third p-type zone (Zp3) and a third n-type zone (Zn3) forming a diode (DI) configured to be reverse biased.

5. The directly modulated light source (DMD) according to claim 1, wherein the intrinsic zone (Zi) of the horizontal laser diode (DH) is optically coupled to a distributed feedback grating (DFB).

6. A light source according to claim 1, wherein the substrate is made of InP or GaAs material.

7. The directly modulated light source (DMD) according to claim 1, the directly modulated light source (DMD) further comprising a semi-insulating layer (CSI) made of crystalline material arranged on the substrate and in contact with the blocking layer (CB) and the second n-type doped zone (Zn2).

8. The directly modulated light source (DMD) according to claim 7, wherein the substrate and the semi-insulating layer are made of InP material.
